(19) United States
(12) Patent Application Publication
(10) Pub. No.: US 2006/0085583 A1
(43) Pub. Date: Apr. 20, 2006

(54) Multi-functional integrated circuit card module with a mixed interface

(75) Inventors: Gordon Yu, Taipei City (TW); Hung-Tse Ho, Taipei City (TW); Chien-Wei Teng, Miaoli City (TW); Ming-Che Chang, Tainan City (TW); I-Hua Ho, Kaohsiung City (TW)

Correspondence Address: BACON & THOMAS, PLLC, 625 SLATERS LANE, FOURTH FLOOR, ALEXANDRIA, VA, 22314, US

(73) Assignee: C-One Technology Corporation, Hsin-Chu City (TW)

(21) Appl. No.: 11/024,797

(22) Filed: Dec. 30, 2004

(30) Foreign Application Priority Data
Oct. 15, 2004 (TW) 093131407

(51) Int. Cl. G06F 12/14; H05K 7/10

(52) U.S. Cl. 710/301; 711/115

(57) ABSTRACT

The present invention provides a multi-functional integrated circuit card module with a mixed interface, which comprises a controller, multiple first pins and second pins coupled to the controller, and a non-volatile memory whose read/write function is controlled by the controller. The controller works at a first mode after detecting the first pins complying with first interface characteristics while the second pins not complying with second interface characteristics; and the controller works at the first mode plus a second mode after detecting the first pins complying with the first interface characteristics and the second complying with the second interface characteristics.

### BACKGROUND OF THE INVENTION

1. Field of the Invention

The present invention relates to an integrated circuit (IC) module, and more particularly, to a multi-functional IC module with a mixed interface.

2. Description of Related Art

Currently, with the development of electronic technology, all kinds of electronic devices, such as laptops, Palm computers or personal digital assistants (PDA), are getting smaller. Due to the portability and powerful operation capability, the small electronic devices provide a great convenience for users. However, since the electronic devices are quite small in size, such kind of small electronic devices are only equipped with basic memory. The function of extending memory capacity of these small electronic devices can only be implemented by using a memory module, like a memory card or a USB drive.

An integrated circuit card module, such as a subscriber identity module (SIM) or a Smart Card module, is capable of not only providing the aforesaid passive memory function, but also providing an active certification or control function. However, due to the variety of electronic devices each requiring different integrated circuit card modules, the user has to possess multiple integrated circuit card modules at the same time thereby causing the usage and management inconvenience. Alternatively, due to the integration of electronic device functions, one electronic device may be inserted with different integrated circuit card modules. For example, a camera phone has to be inserted with a SIM card for providing a certification function, and also has to be inserted with a memory card for extending the memory capacity for storing taken photos thereby also causing the usage inconvenience.

Therefore, it is desirable to provide an improved multi-functional integrated circuit card module with a mixed interface to mitigate and/or obviate the aforementioned problems.

### SUMMARY OF THE INVENTION

The object of the present invention is to provide a multi-functional integrated circuit card module with a mixed interface for eliminating the aforementioned drawbacks with conventional integrated circuit card module.

To achieve the object, there is provided a multi-functional integrated circuit card module with a mixed interface for being inserted in a host. The multi-functional integrated circuit card module with a mixed interface comprises: a controller; a plurality of first pins coupled to the controller; a plurality of second pins coupled to the controller; and a non-volatile memory coupled to the controller such that the controller controls a read/write function of the non-volatile memory; wherein the controller works at a first mode after detecting the first pins complying with first interface characteristics while the second pins not complying with second interface characteristics; and the controller works at the first mode plus a second mode after detecting the first pins complying with the first interface characteristics and the second pins complying with the second interface characteristics.

Other objects, advantages, and novel features of the invention will become more apparent from the following detailed description when taken in conjunction with the accompanying drawings.

### BRIEF DESCRIPTION OF THE DRAWINGS

FIG. 1 illustrates a system structure of the multi-functional integrated circuit card module with a mixed interface according to the present invention;

FIG. 2 depicts the pin distribution of a first embodiment of the multi-functional integrated circuit card module with a mixed interface according to the present invention;

FIG. 3 is a flowchart of the first embodiment of the multi-functional integrated circuit card module with a mixed interface according to the present invention;

FIG. 4 depicts the pin distribution of a second embodiment of the multi-functional integrated circuit card module with a mixed interface according to the present invention; and

FIG. 5 is a flowchart of the second embodiment of the multi-functional integrated circuit card module with a mixed interface according to the present invention.

### DETAILED DESCRIPTION OF THE PREFERRED EMBODIMENT

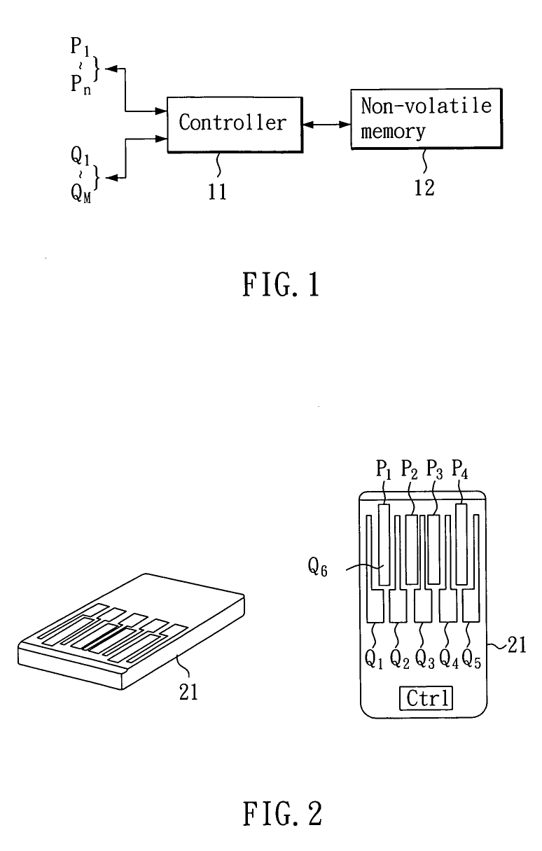

Please refer to FIG. 1. FIG. 1 illustrates the system structure of the multi-functional integrated circuit card module with a mixed interface according to the present invention. The multi-functional integrated circuit card module with a mixed interface comprises a controller 11, a non-volatile memory 12, and multiple first pins P₁˜Pₙ and second pins Q₁˜Qₘ coupled to the controller 11. The non-volatile memory 12 is preferably a flash memory which is coupled to the controller 11, such that the controller 11 controls a read/write function of the flash memory.

The aforementioned first pins P₁˜Pₙ and second pins Q₁˜Qₘ are respectively compatible with the pins of two different kinds of integrated circuit card module. With reference to FIG. 2, the first pins P₁˜Pₙ and second pins Q₁˜Qₘ of the multi-functional integrated circuit card module with a mixed interface according to the first embodiment are distributed on a terminal 21. The first pins P₁˜P₄ are USB pins (VDD, D+, D−, GND), and the second pins Q₁˜Q₆ are Smart Card pins (VDD, RST, CLK, VPP, I/O, GND). The second pin Q₆ and the first pin P₁ are a common ground pin (GND). The first pins P₁˜P₄ and second pins Q₁˜Q₅ are distributed on the terminal 21 in a mixed way, wherein the first pins P₁˜P₄ are arranged in the front of the terminal 21 according to the USB standard, while the second pins Q₁˜Q₅ are arranged behind the first pins P₁˜P₄ and respectively extended to the front of the terminal 21. In such regard, the integrated circuit card module could be inserted into a host slot (not shown in figures) if the host slot has pins corresponding to the first pins P₁˜P₄ or the second pins Q₁-Q₆. Further, the above second pins Q₁˜Q₅ and first pins P₁˜P₄ as a total of nine pins can also be configured as MMC/SD pins (CMD, VSS1, VDD, CLK, VSS2, DATA0, DATA1˜3), and the terminal 21 can be switched through a switch (not shown in figures) to MMC/SD standard for being inserted into the MMC/SD slot of the host.

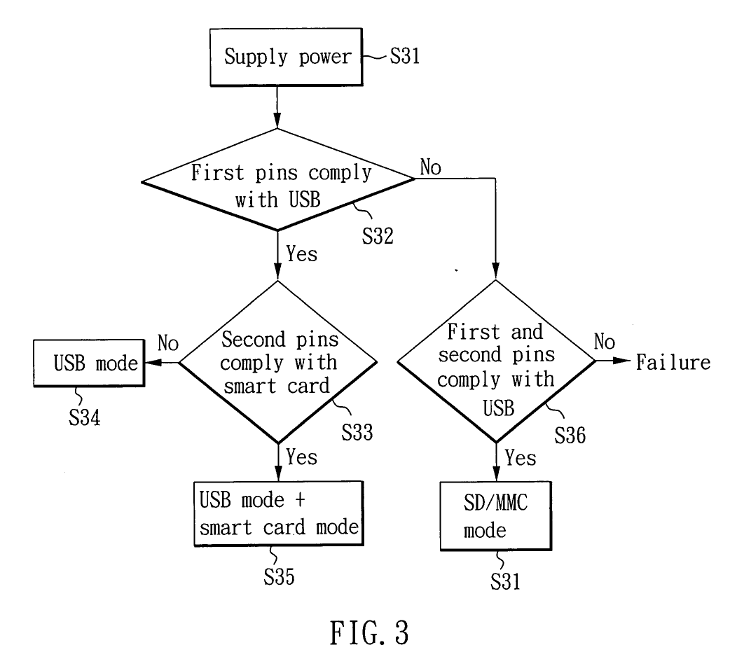

Please refer to FIG. 1 and FIG. 3, wherein FIG. 3 illustrates a flowchart of the first embodiment of the multi-functional integrated circuit card module according to the present invention. At the moment the multi-functional integrated circuit card module is inserted in the host slot (not shown in figures), the host starts to supply power for the multi-functional integrated circuit card module (S31). Meanwhile, the multi-functional controller 11 detects whether the first pins P₁˜P₄ comply with USB interface characteristics. For example, the controller 11 detects whether the potential of the power pin P₁ is greater than a predetermined potential, such as 4.7V (S32). If so, the controller 11 then detects whether the second pins Q₁˜Q₅ comply with Smart Card interface characteristics. For example, the controller 11 detects whether the RST pin Q₂ receives signals from the host (S33). In step S33, if the controller 11 detects that the RST pin Q₂ doesn't receive any signal from the host, the multi-functional controller 11 would be configured to work at the USB mode (S34); otherwise, the multi-functional controller 11 would be configured to work at a mixed mode as the USB mode plus the Smart Card mode (S35). Further, in step S32, if first pins P₁˜P₄ are determined as not complying with the USB interface characteristics, the controller 11 would detect whether the second pins Q₁˜Q₅ and first pins P₁˜P₄ comply with SD/MMC interface characteristics. For example, the controller 11 detects whether the CMD pin Q₁ receives CMD or ACMD signals (S36), if not, the multi-functional integrated circuit card module would be disabled; otherwise, the multi-functional controller 11 would be configured to work at the SD/MMC mode (S37), wherein the multi-functional controller 11 works at the MMC mode if the CMD pin Q₁ receives CMD0, CMD1, CMD2 and CMD3, while the multi-functional controller 11 works at the SD mode if the CMD pin Q₁ receives CMD0, ACMD41, CMD2 and CMD3.

When the multi-functional controller 11 works at the USB mode, it controls the flash memory 12 to provide the function of extending memory capacity. When the multi-functional controller 11 works at the USB mode plus the Smart Card mode, it co-operates with part of the flash memory 12 to provide the certification or control function; meanwhile, it also controls the flash memory 12 to provide the function of extending memory capacity. When the multi-functional controller 11 works at the SD/MMC mode, it controls the flash memory 12 to provide the function of extending memory capacity.

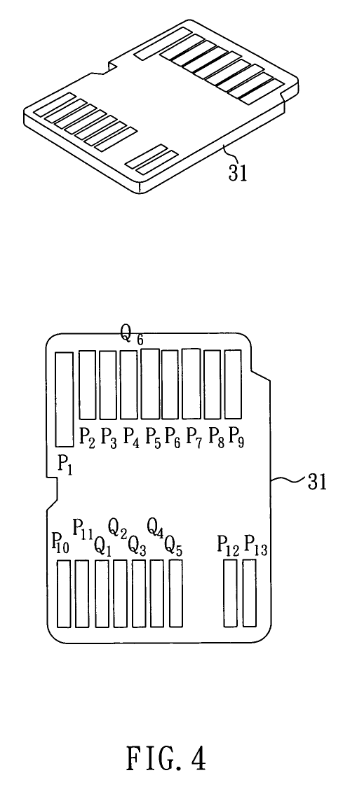

With reference to FIG. 4, it depicts that the first pins P₁˜Pₙ and second pins Q₁˜Qₘ of the multi-functional integrated circuit card module with a mixed interface are distributed on a card 31. In this embodiment, the first pins P₁˜P₁₃ are MMC/SD pins (CMD, VSS1, VDD, CLK, VSS2, DATA0, DATA1˜7), wherein the first pins P₁˜P₉ are SD pins; and the second pins Q₁˜Q₆ are Smart Card pins. The second pin Q₆ and the first pin P₄ are a common ground pin (GND). The first pins P₁˜P₁₃ and second pins Q₁˜Q₅ are respectively distributed on both ends of the card 31, wherein the first pins P₁˜P₁₃ are arranged in the front end and both sides of the rear end of the card 31, while the second pins Q₁˜Q₅ are arranged in the middle of the rear end of the card 31 according to the Smart Card standard. In such regard, the integrated circuit card module could be inserted into a host slot (not shown in figures) if the host slot has pins corresponding to the first pins P₁˜P₁₃ or the second pins Q₁˜Q₆.

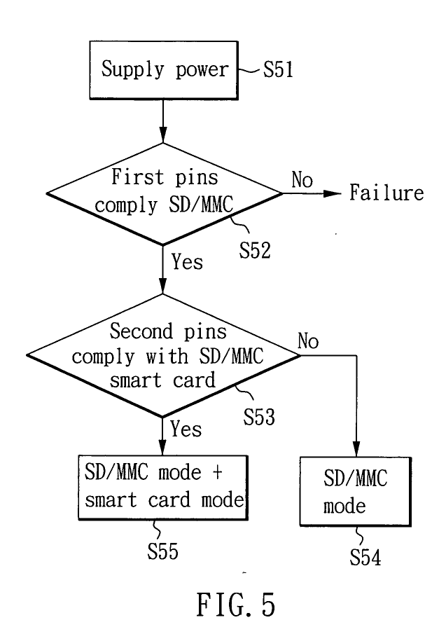

Please refer to FIG. 1 and FIG. 5, wherein FIG. 5 illustrates a flowchart of the second embodiment of the multi-functional integrated circuit module according to the present invention. At the moment the multi-functional integrated circuit card module is inserted in the host slot (not shown in figures), the host starts to supply power for the multi-functional integrated circuit card module (S51). Meanwhile, the multi-functional controller 11 detects whether the first pins P₁˜P₁₃ comply with SD/MMC interface characteristics. For example, the controller 11 detects whether the CMD pin P₁ receives CMD or ACMD signals (S52), if not, the multi-functional integrated circuit card module would be disabled. Otherwise, the controller 11 further detects whether the second pins Q₁˜Q₅ comply with the Smart Card interface characteristics. For example, it detects whether the RST pin Q₂ receives signals from the host (S53). If the RST pin Q₂ doesn't’ receive any signal from the host, the multi-functional controller 11 would be configured to work at the SD/MMC mode (S54); otherwise, it would be configured to work at a mixed mode as the SD/MMC mode plus the Smart Card mode (S55), wherein the multi-functional controller 11 works at the MMC mode if the CMD pin Q₁ receives CMD0, CMD1, CMD2 and CMD3, while the multi-functional controller 11 works at the SD mode if the CMD pin Q₁ receives CMD0, ACMD41, CMD2 and CMD3.

When the multi-functional controller 11 works at the SD/MMC mode, it controls the flash memory 12 to provide the function of extending memory capacity. When the multi-functional controller 11 works at the SD/MMC mode plus the Smart Card mode, it co-operates with part of the flash memory 12 to provide the certification or control function; meanwhile, it also controls the flash memory 12 to provide the function of extending the memory capacity.

According to the description mentioned above, the multi-functional integrated circuit card mode with a mixed interface of the present invention provides the passive memory function and the active certification or control function, and provides various interfaces suitable for different electronic devices, thereby achieving the efficiency of convenient usage and management of the integrated circuit card module.

Although the present invention has been explained in relation to its preferred embodiment, it is to be understood that many other possible modifications and variations can be made without departing from the spirit and scope of the invention as hereinafter claimed.

What is claimed is:

1. A multi-functional integrated circuit card module with a mixed interface for being inserted in a host, comprising:
a controller;
a plurality of first pins coupled to the controller;
a plurality of second pins coupled to the controller; and
a non-volatile memory coupled to the controller such that the controller controls a read/write function of the non-volatile memory;
wherein the controller works at a first mode after detecting the first pins complying with first interface characteristics while the second pins not complying with second interface characteristics; and the controller works at the first mode plus a second mode after detecting the first pins complying with the first interface characteristics and the second pins complying with the second interface characteristics.

2. The multi-functional integrated circuit card module with a mixed interface as claimed in claim 1, wherein the first pins complying with the first interface characteristics represents that the potential of a first predetermined pin of the first pins is greater than a predetermined value, the second pins complying with the second interface characteristics represents that a second predetermined pin of the second pins receives signals from the host.

3. The multi-functional integrated circuit card module with a mixed interface as claimed in claim 2, wherein the first pins are USB pins, the second pins are Smart Card pins, the first mode is a USB mode, and the second mode is a Smart Card mode.

4. The multi-functional integrated circuit card module with a mixed interface as claimed in claim 3, wherein the controller works at the USB mode for providing a function of extending memory capacity by controlling the non-volatile memory.

5. The multi-functional integrated circuit card module with a mixed interface as claimed in claim 3, wherein the controller works at the USB mode plus the Smart Card mode for providing a certification or control function by using part of the non-volatile memory, and providing a function of extending memory capacity by controlling the non-volatile memory.

6. The multi-functional integrated circuit card module with a mixed interface as claimed in claim 3, wherein the first predetermined pin is a power pin of the USB pins.

7. The multi-functional integrated circuit card module with a mixed interface as claimed in claim 6, wherein the predetermined value is 4.7V.

8. The multi-functional integrated circuit card module with a mixed interface as claimed in claim 3, wherein the second predetermined pin is a RST pin of the Smart Card pins.

9. The multi-functional integrated circuit card module with a mixed interface as claimed in claim 2, wherein the controller works at a third mode after detecting the first pins not complying with the first interface characteristics while the first pins and the second pins complying with third interface characteristics.

10. The multi-functional integrated circuit card module with a mixed interface as claimed in claim 9, wherein the first pins and the second pins complying with the third interface characteristics represents that a third predetermined pin of the first pins and the second pins receives a predetermined signal.

11. The multi-functional integrated circuit card module with a mixed interface as claimed in claim 10, wherein the first pins and the second pins are SD/MMC pins, and the third mode is a SD/MMC mode.

12. The multi-functional integrated circuit card module with a mixed interface as claimed in claim 11, wherein the controller works at the SD/MMC mode for providing a function of extending memory capacity by controlling the non-volatile memory.

13. The multi-functional integrated circuit card module with a mixed interface as claimed in claim 11, wherein the third predetermined pin is a CMD pin of the SD/MMC pins, and the predetermined signal is a CMD or ACMD signal.

14. The multi-functional integrated circuit card module with a mixed interface as claimed in claim 2, wherein the non-volatile memory is a flash memory.

15. The multi-functional integrated circuit card module with a mixed interface as claimed in claim 2, further comprising a terminal with the first pins and the second pins distributed thereon.

16. The multi-functional integrated circuit card module with a mixed interface as claimed in claim 15, wherein the first pins and the second pins are distributed on the terminal in a mixed way, the first pins are arranged in the front of the terminal, while the second pins are arranged behind the first pins and respectively extended to the front of the terminal.

17. The multi-functional integrated circuit card module with a mixed interface as claimed in claim 2, wherein the first pins are SD/MMC pins, the second pins are Smart Card pins, the first mode is a SD/MMC mode, and the second mode is a Smart Card mode.

18. The multi-functional integrated circuit card module with a mixed interface as claimed in claim 17, wherein the controller works at the SD/MMC mode for providing a function of extending memory capacity by controlling the non-volatile memory.

19. The multi-functional integrated circuit card module with a mixed interface as claimed in claim 17, wherein the controller works at the SD/MMC mode plus the Smart Card mode for providing a certification or control function by using part of the non-volatile memory, and providing a function for extending memory capacity by controlling the non-volatile memory.

20. The multi-functional integrated circuit card module with a mixed interface as claimed in claim 17, wherein the first predetermined pin is a CMD pin of the SD/MMC pins, and the predetermined signal is a CMD or ACMD signal.

21. The multi-functional integrated circuit card module with a mixed interface as claimed in claim 17, wherein the second predetermined pin is a RST pin of the Smart Card pins.

22. The multi-functional integrated circuit card module with a mixed interface as claimed in claim 2, wherein the non-volatile memory is a flash memory.

23. The multi-functional integrated circuit card module with a mixed interface as claimed in claim 17, further comprising a card with the first pins and the second pins distributed thereon.

24. The multi-functional integrated circuit card module with a mixed interface as claimed in claim 23, wherein the first pins and the second pins are distributed on the card in a mixed way, the first pins are arranged in the front of the card, while the second pins are arranged behind the first pins and respectively extended to the front of the card.
